(19) United States
(12) Patent Application Publication
(10) Pub. No.: US 2026/0123108 A1
(43) Pub. Date: Apr. 30, 2026

(54) LIGHT-EMITTING ELEMENT

(71) Applicant: NICHIA CORPORATION, Anan-shi (JP)

(72) Inventor: Akinori KISHI, Tokushima-shi (JP)

(73) Assignee: NICHIA CORPORATION, Anan-shi (JP)

(21) Appl. No.: 19/353,715

(22) Filed: Oct. 9, 2025

(30) Foreign Application Priority Data
Oct. 29, 2024 (JP) 2024-190045
Apr. 23, 2025 (JP) 2025-071753

(51) Int. Cl. H10H 20/831; H10H 20/857

(52) U.S. Cl. CPC H10H 20/831; H10H 20/857

(57) ABSTRACT

A light-emitting element includes a substrate, a semiconductor structure body, an n-electrode, a p-electrode, an n-pad electrode, and a p-pad electrode. The semiconductor structure body includes an n-type semiconductor layer including first and second regions. The n-electrode includes first to third n-electrode regions. The p-electrode includes first to third p-electrode regions. The first region includes first to fourth parts. The first part is positioned between the first n-electrode region and the third p-electrode region. The second part is positioned between the second n-electrode region and the third p-electrode region. The third part is positioned between the first p-electrode region and the third n-electrode region. The fourth part is positioned between the second p-electrode region and the third n-electrode region. A first trench that is recessed downward is located in the first and second parts. The first trench is not located in the third part.

### CROSS-REFERENCE TO RELATED APPLICATIONS

This application is based upon and claims priority to Japanese Patent Application No. 2024-190045, filed on Oct. 29, 2024, and Japanese Patent Application No. 2025-071753, filed on Apr. 23, 2025. The entire contents of these applications are incorporated herein by reference.

### FIELD

Embodiments described herein relate generally to a light-emitting element.

### BACKGROUND

In a light-emitting element, there are cases where current concentrates at the periphery of an n-pad electrode. A technique to solve this problem may be considered in which a trench is formed in the semiconductor structure body at the periphery of the n-pad electrode to make a current path at the periphery of the n-pad electrode longer (that is, to make it difficult for current to flow). However, there is a risk that the forward voltage may increase if the trench is made to surround the n-electrode.

### SUMMARY

Embodiments are directed to a light-emitting element in which an increase of the forward voltage can be suppressed while reducing current concentration at the periphery of the n-pad electrode.

A light-emitting element according to an embodiment of the invention includes a substrate, a semiconductor structure body, an n-electrode, a p-electrode, an n-pad electrode, and a p-pad electrode. The substrate includes a first side and a second side. The first side extends in a first direction in a top-view. The second side is parallel to the first side. The semiconductor structure body includes an n-type semiconductor layer, an active layer, and a p-type semiconductor layer. The n-type semiconductor layer is located on the substrate. The n-type semiconductor layer includes a first region and a second region in a top-view. The active layer is located on the second region. The p-type semiconductor layer is located on the active layer. The n-electrode is located on the first region. The p-electrode is located on the p-type semiconductor layer. The n-pad electrode is located on the n-electrode. The n-pad electrode is more proximate to the first side than the second side in a top-view. The p-pad electrode is located on the p-electrode. The p-pad electrode is more proximate to the second side than the first side in a top-view. The n-electrode includes a first n-electrode region, a second n-electrode region, and a third n-electrode region. The first n-electrode region extends in the first direction and overlaps the n-pad electrode in a top-view. The second n-electrode region extends from the first n-electrode region in a second direction and overlaps the n-pad electrode in a top-view. The second direction is orthogonal to the first direction. The third n-electrode region extends from the second n-electrode region in the second direction and does not overlap the n-pad electrode in a top-view. The p-electrode includes a first p-electrode region, a second p-electrode region, and a third p-electrode region. The first p-electrode region extends in the first direction and overlaps the p-pad electrode in a top-view. The second p-electrode region extends from the first p-electrode region in the second direction and overlaps the p-pad electrode in a top-view. The third p-electrode region extends from the second p-electrode region in the second direction and does not overlap the p-pad electrode in a top-view. The second p-electrode region is arranged with the third n-electrode region in the first direction. The third p-electrode region is arranged with the second n-electrode region in the first direction. The first region includes a first part, a second part, a third part, and a fourth part. The first part is positioned between the first n-electrode region and the third p-electrode region in a top-view. The second part is positioned between the second n-electrode region and the third p-electrode region in a top-view. The third part is positioned between the first p-electrode region and the third n-electrode region in a top-view. The fourth part is positioned between the second p-electrode region and the third n-electrode region in a top-view. A first trench that is recessed downward is located in the first and second parts. The first trench is not located in the third part.

A light-emitting element according to an embodiment of the invention includes a substrate, a semiconductor structure body, an n-electrode, a p-electrode, an n-pad electrode, and a p-pad electrode. The substrate includes a first side and a second side. The first side extends in a first direction in a top-view. The second side is parallel to the first side. The semiconductor structure body includes an n-type semiconductor layer, an active layer, and a p-type semiconductor layer. The n-type semiconductor layer is located on the substrate. The n-type semiconductor layer includes a first region and a second region in a top-view. The active layer is located on the second region. The p-type semiconductor layer is located on the active layer. The n-electrode is located on the first region. The p-electrode is located on the p-type semiconductor layer. The n-pad electrode is located on the n-electrode. The n-pad electrode is more proximate to the first side than the second side in a top-view. The p-pad electrode is located on the p-electrode. The p-pad electrode is more proximate to the second side than the first side in a top-view. The n-electrode includes a first n-electrode region, a second n-electrode region, and a third n-electrode region. The first n-electrode region extends in the first direction and overlaps the n-pad electrode in a top-view. The second n-electrode region extends from the first n-electrode region in a second direction and overlaps the n-pad electrode in a top-view. The second direction is orthogonal to the first direction. The third n-electrode region extends from the second n-electrode region in the second direction and does not overlap the n-pad electrode in a top-view. The p-electrode includes a first p-electrode region, a second p-electrode region, and a third p-electrode region. The first p-electrode region extends in the first direction and overlaps the p-pad electrode in a top-view. The second p-electrode region extends from the first p-electrode region in the second direction and overlaps the p-pad electrode in a top-view. The third p-electrode region extends from the second p-electrode region in the second direction and does not overlap the p-pad electrode in a top-view. The second p-electrode region is arranged with the third n-electrode region in the first direction. The third p-electrode region is arranged with the second n-electrode region in the first direction. The first region includes a first part, a second part, a third part, and a fourth part. The first part is positioned between the first n-electrode region and the third p-electrode region in a top-view. The second part is positioned between the second n-electrode region and the third p-electrode region in a top-view. The third part is positioned between the first p-electrode region and the third n-electrode region in a top-view. The fourth part is positioned between the second p-electrode region and the third n-electrode region in a top-view. A first trench that is recessed downward is located in the first and second parts. A second trench that is recessed downward is located in at least one of the third part or the fourth part. A depth of the second trench is less than a depth of the first trench.

A light-emitting element according to an embodiment of the invention includes a substrate, a semiconductor structure body, an n-electrode, a p-electrode, an n-pad electrode, and a p-pad electrode. The substrate includes a first side and a second side. The first side extends in a first direction in a top-view. The second side is parallel to the first side. The semiconductor structure body includes an n-type semiconductor layer, an active layer, and a p-type semiconductor layer. The n-type semiconductor layer is located on the substrate. The n-type semiconductor layer includes a first region and a second region in a top-view. The active layer is located on the second region. The p-type semiconductor layer is located on the active layer. The n-electrode is located on the first region. The p-electrode is located on the p-type semiconductor layer. The n-pad electrode is located on the n-electrode. The n-pad electrode is more proximate to the first side than the second side in a top-view. The p-pad electrode is located on the p-electrode. The p-pad electrode is more proximate to the second side than the first side in a top-view. The n-electrode includes a first n-electrode region, a second n-electrode region, and a third n-electrode region. The first n-electrode region extends in the first direction and overlaps the n-pad electrode in a top-view. The second n-electrode region extends from the first n-electrode region in a second direction and overlaps the n-pad electrode in a top-view. The second direction is orthogonal to the first direction. The third n-electrode region extends from the second n-electrode region in the second direction and does not overlap the n-pad electrode in a top-view. The p-electrode includes a first p-electrode region, a second p-electrode region, and a third p-electrode region. The first p-electrode region extends in the first direction and overlaps the p-pad electrode in a top-view. The second p-electrode region extends from the first p-electrode region in the second direction and overlaps the p-pad electrode in a top-view. The third p-electrode region extends from the second p-electrode region in the second direction and does not overlap the p-pad electrode in a top-view. The second p-electrode region is arranged with the third n-electrode region in the first direction. The third p-electrode region is arranged with the second n-electrode region in the first direction. The first region includes a first part, a second part, a third part, and a fourth part. The first part is positioned between the first n-electrode region and the third p-electrode region in a top-view. The second part is positioned between the second n-electrode region and the third p-electrode region in a top-view. The third part is positioned between the first p-electrode region and the third n-electrode region in a top-view. The fourth part is positioned between the second p-electrode region and the third n-electrode region in a top-view. A first trench that is recessed downward is located in the first and second parts. A second trench that is recessed downward is located in at least one of the third part or the fourth part. A width in the first direction of the second trench is less than a width in the first direction of the first trench.

According to an embodiment of the invention, a light-emitting element can be realized in which an increase of the forward voltage can be suppressed while reducing current concentration at the periphery of the n-pad electrode.

### BRIEF DESCRIPTION OF THE DRAWINGS

FIG. 1 is a plan view schematically showing a light-emitting element according to a first embodiment;

FIG. 2 is a cross-sectional view schematically showing the light-emitting element according to the first embodiment;

FIG. 3 is a cross-sectional view schematically showing the light-emitting element according to the first embodiment;

FIG. 4 is a cross-sectional view schematically showing the light-emitting element according to the first embodiment;

FIG. 5 is a plan view schematically showing a light-emitting element according to a first modification of the first embodiment;

FIG. 6 is a cross-sectional view schematically showing the light-emitting element according to the first modification of the first embodiment;

FIG. 7 is a cross-sectional view schematically showing the light-emitting element according to the first modification of the first embodiment;

FIG. 8 is a cross-sectional view schematically showing the light-emitting element according to the first modification of the first embodiment;

FIG. 9 is a plan view schematically showing a light-emitting element according to a second modification of the first embodiment;

FIG. 10 is a plan view schematically showing a light-emitting element according to a third modification of the first embodiment;

FIG. 11 is a plan view schematically showing a light-emitting element according to a fourth modification of the first embodiment;

FIG. 12 is a plan view schematically showing a light-emitting element according to a second embodiment;

FIG. 13 is a cross-sectional view schematically showing the light-emitting element according to the second embodiment;

FIG. 14 is a cross-sectional view schematically showing the light-emitting element according to the second embodiment;

FIG. 15 is a cross-sectional view schematically showing the light-emitting element according to the second embodiment;

FIG. 16 is a plan view schematically showing a light-emitting element according to a first modification of the second embodiment;

FIG. 17 is a plan view schematically showing a light-emitting element according to a second modification of the second embodiment;

FIG. 18 is a plan view schematically showing a light-emitting element according to a third modification of the second embodiment;

FIG. 19 is a plan view schematically showing a light-emitting element according to a fourth modification of the second embodiment;

FIG. 20 is a plan view schematically showing a light-emitting element according to a fifth modification of the second embodiment;

FIG. 21 is a plan view schematically showing a light-emitting element according to a third embodiment.

FIG. 22 is a cross-sectional view schematically showing the light-emitting element according to the third embodiment;

FIG. 23 is a cross-sectional view schematically showing the light-emitting element according to the third embodiment;

FIG. 24 is a cross-sectional view schematically showing the light-emitting element according to the third embodiment; and

FIG. 25 is a cross-sectional view schematically showing a light-emitting element according to a fifth modification of the first embodiment.

### DETAILED DESCRIPTION

Exemplary embodiments will now be described with reference to the drawings.

The drawings are schematic or conceptual, and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a drawing thereinabove are marked with like reference numerals, and a detailed description is omitted as appropriate. End views that show only cross sections may be used as cross-sectional views.

For easier understanding of the following description, the arrangements and configurations of the portions are described using an XYZ orthogonal coordinate system. An X-axis, a Y-axis, and a Z-axis are orthogonal to each other. A direction in which the X-axis extends is referred to as an “X-direction,” a direction in which the Y-axis extends is referred to as a “Y-direction,” and a direction in which the Z-axis extends is referred to as a “Z-direction.” For easier understanding of the description, the direction of the arrow of the Z-direction may be referred to as up or above, and the opposite direction may be referred to as down or below, but these directions are independent of the direction of gravity. A view downward from above is referred to as “viewed in top-view.” The Z-direction length is referred to as the “thickness.” According to the embodiments below, a first direction is referred to as the Y-direction, and a second direction is referred to as the X-direction. A drawing in which a light-emitting element is observed in top-view is referred to as a “plan view.”

### First Embodiment

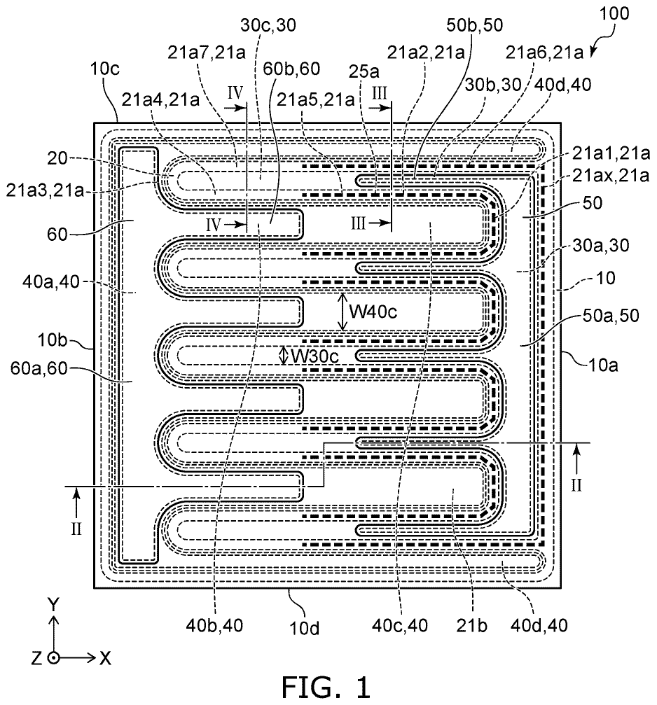

FIG. 1 is a plan view schematically showing a light-emitting element according to a first embodiment.

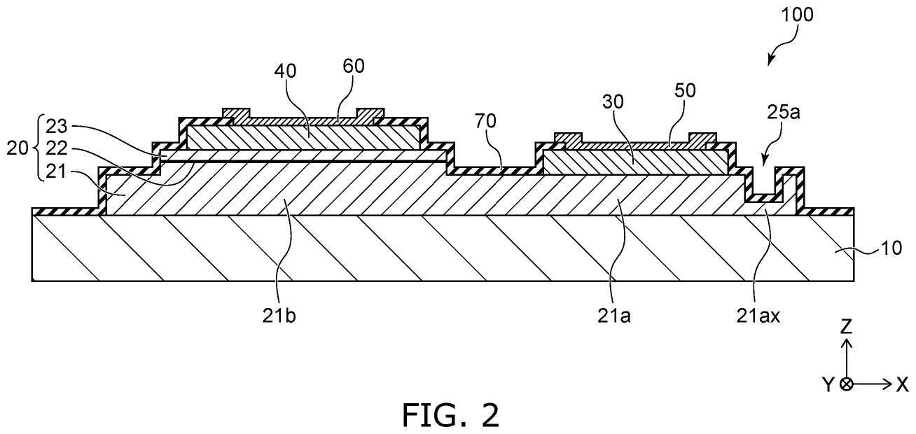

FIGS. 2 to 4 are cross-sectional views schematically showing the light-emitting element according to the first embodiment.

FIG. 2 is a cross-sectional view along line II-II shown in FIG. 1.

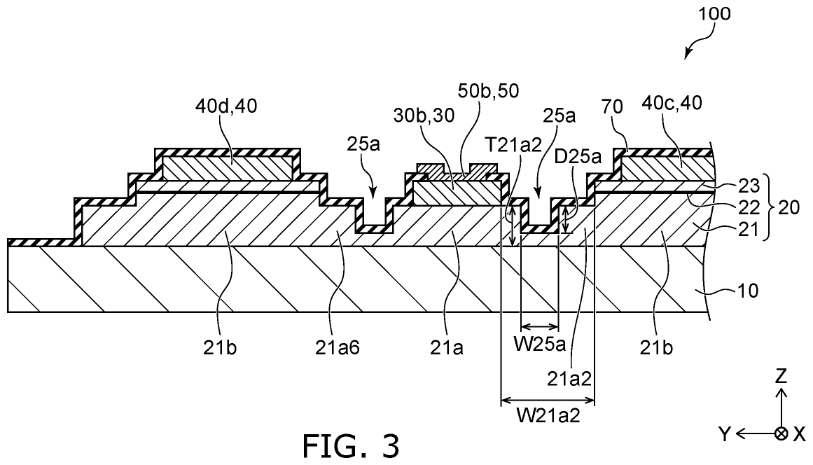

FIG. 3 is a cross-sectional view along line III-III shown in FIG. 1.

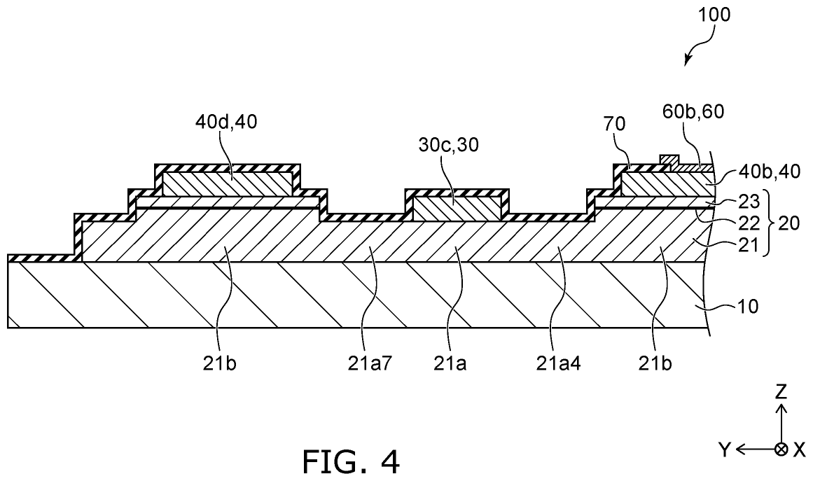

FIG. 4 is a cross-sectional view along line IV-IV shown in FIG. 1.

As shown in FIGS. 1 to 4, the light-emitting element 100 according to the first embodiment includes a substrate 10, a semiconductor structure body 20, an n-electrode 30, a p-electrode 40, an n-pad electrode 50, and a p-pad electrode 60.

### Substrate

The substrate 10 is located in the lowermost part of the light-emitting element 100. The upper surface and lower surface of the substrate 10 each are substantially parallel to the X-Y plane. The substrate 10 includes a first side 10a and a second side 10b. The first side 10a extends in the first direction (the Y-direction) in a top-view. The second side 10b is parallel to the first side 10a in a top-view. In the light-emitting element 100, the substrate 10 is rectangular in a top-view. In a top-view, the substrate 10 includes the first side 10a and the second side 10b which are parallel to each other, and a third side 10c and a fourth side 10d which are parallel to each other and connect the first side 10a and the second side 10b. The third side 10c and the fourth side 10d extend in the second direction (the X-direction) in a top-view. When the substrate 10 is rectangular in a top-view, the length of one side of the substrate 10 is, for example, not less than 500 μm and not more than 2,000 μm. It is sufficient for the shape of the substrate 10 in a top-view to include the first side 10a and the second side 10b; the shape may be, for example, polygonal other than rectangular.

The substrate 10 includes, for example, sapphire. The thickness of the substrate 10 is, for example, not less than 50 μm and not more than 1,000 μm, favorably not less than 100 μm and not more than 800 μm, and more favorably not less than 300 μm and not more than 800 μm.

### Semiconductor Structure Body

The semiconductor structure body 20 is located on the substrate 10. The semiconductor structure body 20 contacts the upper surface of the substrate 10. The semiconductor structure body 20 includes an n-type semiconductor layer 21, an active layer 22, and a p-type semiconductor layer 23. The n-type semiconductor layer 21 includes a first region 21a and a second region 21b in a top-view. The active layer 22 is located on the second region 21b of the n-type semiconductor layer 21. The active layer 22 contacts the second region 21b. The p-type semiconductor layer 23 is located on the active layer 22. The p-type semiconductor layer 23 contacts the active layer 22. The active layer 22 and the p-type semiconductor layer 23 are not located on the first region 21a. The upper surfaces and lower surfaces of the n-type semiconductor layer 21, the active layer 22, and the p-type semiconductor layer 23 each are substantially parallel to the X-Y plane.

The semiconductor structure body 20 is made of a nitride semiconductor. In the specification, “nitride semiconductor” includes, for example, all compositions of semiconductors of the chemical formula InₓAl_{y}Ga_{1-x-y}N (0≤x≤1, 0≤y≤1, and x+y≤1) for which the composition ratios x and y are changed within the ranges respectively. “Nitride semiconductor” further includes Group V elements other than N (nitrogen) in the chemical formula above, various elements added to control various properties such as the conductivity type, etc. The n-type semiconductor layer 21 includes a semiconductor that includes an n-type impurity. The n-type impurity included in the n-type semiconductor layer 21 is, for example, silicon (Si) or phosphorus (P). The p-type semiconductor layer 23 includes a semiconductor layer that includes a p-type impurity. The p-type impurity included in the p-type semiconductor layer 23 is, for example, magnesium (Mg) or zinc (Zn). For example, the semiconductor structure body 20 emits violet or ultraviolet light. The peak wavelength of the light emitted by the semiconductor structure body 20 is, for example, not less than 250 nm and not more than 410 nm. The thickness of the semiconductor structure body 20 is, for example, not less than 5 μm and not more than 10 μm.

n-Electrode

The n-electrode 30 is located on the first region 21a of the n-type semiconductor layer 21. The n-electrode 30 contacts the first region 21a. The upper surface and lower surface of the n-electrode 30 each are substantially parallel to the X-Y plane. The n-electrode 30 includes a first n-electrode region 30a, a second n-electrode region 30b, and a third n-electrode region 30c. The first n-electrode region 30a extends in the first direction (the Y-direction) in a top-view. The first n-electrode region 30a overlaps the n-pad electrode 50 in a top-view. The second n-electrode region 30b extends from the first n-electrode region 30a in the second direction (the X-direction) in a top-view. The second direction is orthogonal to the first direction. The second n-electrode region 30b overlaps the n-pad electrode 50 in a top-view. The third n-electrode region 30c extends from the second n-electrode region 30b in the second direction (the X-direction) in a top-view. The third n-electrode region 30c does not overlap the n-pad electrode 50 in a top-view.

In the light-emitting element 100, the n-electrode 30 includes one first n-electrode region 30a, five second n-electrode regions 30b, and five third n-electrode regions 30c. The third n-electrode regions 30c extend in the second direction (the X-direction) respectively from different second n-electrode regions 30b. In the light-emitting element 100, the n-electrode 30 includes five second n-electrode regions 30b. The number of the second n-electrode regions 30b is equal to the number of the third n-electrode regions 30c. Although multiple second n-electrode regions 30b and multiple third n-electrode regions 30c are shown in the example according to the embodiment, the number of the second n-electrode regions 30b and the number of the third n-electrode regions 30c may be one.

The n-electrode 30 includes, for example, at least one selected from the group consisting of titanium (Ti), nickel (Ni), aluminum silicon alloy (AlSi), tantalum (Ta), rhodium (Rh), and ruthenium (Ru). The thickness of the n-electrode 30 is, for example, not less than 0.1 μm and not more than 2 μm.

p-Electrode

The p-electrode 40 is located on the p-type semiconductor layer 23. The p-electrode 40 contacts the p-type semiconductor layer 23. The upper surface and lower surface of the p-electrode 40 each are substantially parallel to the X-Y plane. The p-electrode 40 includes a first p-electrode region 40a, a second p-electrode region 40b, and a third p-electrode region 40c. The first p-electrode region 40a extends in the first direction (the Y-direction) in a top-view. The first p-electrode region 40a overlaps the p-pad electrode 60 in a top-view. The second p-electrode region 40b extends from the first p-electrode region 40a in the second direction (the X-direction) in a top-view. The second p-electrode region 40b overlaps the p-pad electrode 60 in a top-view. The third p-electrode region 40c extends from the second p-electrode region 40b in the second direction (the X-direction) in a top-view. The third p-electrode region 40c does not overlap the p-pad electrode 60 in a top-view.

In the light-emitting element 100, the p-electrode 40 includes one first p-electrode region 40a, four second p-electrode regions 40b, and four third p-electrode regions 40c. The third p-electrode regions 40c extend in the second direction (the X-direction) respectively from different second p-electrode regions 40b. The number of the second p-electrode regions 40b is equal to the number of the third p-electrode regions 40c. Although multiple second p-electrode regions 40b and multiple third p-electrode regions 40c are shown in the example according to the embodiment, the number of the second p-electrode regions 40b and the number of the third p-electrode regions 40c may be one.

In the light-emitting element 100, the p-electrode 40 further includes two fourth p-electrode regions 40d. The fourth p-electrode regions 40d extend from the first p-electrode regions 40a in the second direction (the X-direction) in a top-view. The fourth p-electrode regions 40d do not overlap the p-pad electrode 60 in a top-view. Four second p-electrode regions 40b and four third p-electrode regions 40c are positioned between two fourth p-electrode regions 40d in the first direction (the Y-direction). The number of the fourth p-electrode regions 40d may be one. The fourth p-electrode region 40d may be omitted.

The second p-electrode region 40b is arranged with the third n-electrode region 30c in the first direction (the Y-direction). The second p-electrode region 40b is positioned between two third n-electrode regions 30c adjacent to each other in the first direction (the Y-direction). The third n-electrode region 30c is positioned between two second p-electrode regions 40b adjacent to each other in the first direction (the Y-direction). The third p-electrode region 40c is arranged with the second n-electrode region 30b in the first direction (the Y-direction). The third p-electrode region 40c is positioned between two second n-electrode regions 30b adjacent to each other in the first direction (the Y-direction). The second n-electrode region 30b is positioned between two third p-electrode regions 40c adjacent to each other in the first direction (the Y-direction). The first n-electrode region 30a is arranged with the third p-electrode region 40c in the second direction (the X-direction). The first p-electrode region 40a is arranged with the third n-electrode region 30c in the second direction (the X-direction).

The p-electrode 40 includes, for example, at least one selected from the group consisting of rhodium (Rh), ruthenium (Ru), titanium (Ti), nickel (Ni), and gold (Au). The thickness of the p-electrode 40 is, for example, not less than 0.1 μm and not more than 1 μm. The reflectance of the p-electrode 40 for the peak wavelength of the light emitted by the semiconductor structure body 20 is greater than the reflectance of the n-electrode 30 for the peak wavelength of the light emitted by the semiconductor structure body 20.

n-Pad Electrode

The n-pad electrode 50 is located on the n-electrode 30. The n-pad electrode 50 contacts the n-electrode 30. The upper surface and lower surface of the n-pad electrode 50 each are substantially parallel to the X-Y plane. The n-pad electrode 50 is more proximate to the first side 10a than the second side 10b in a top-view. That is, the distance between the n-pad electrode 50 and the first side 10a is less than the distance between the n-pad electrode 50 and the second side 10b in a top-view.

The n-pad electrode 50 includes a first n-pad electrode region 50a and a second n-pad electrode region 50b. The first n-pad electrode region 50a extends in the first direction (the Y-direction) in a top-view. The second n-pad electrode region 50b extends from the first n-pad electrode region 50a in the second direction (the X-direction) in a top-view.

In the light-emitting element 100, the n-pad electrode 50 includes one first n-pad electrode region 50a and five second n-pad electrode regions 50b. The first n-electrode region 30a overlaps the first n-pad electrode region 50a in a top-view. The second n-electrode regions 30b overlap the second n-pad electrode regions 50b in a top-view. The number of the second n-pad electrode regions 50b is equal to the number of the second n-electrode regions 30b.

The n-pad electrode 50 includes, for example, at least one selected from the group consisting of Ti, platinum (Pt), Ni, and Au. The thickness of the n-pad electrode 50 is, for example, not less than 0.3 μm and not more than 1 μm.

p-Pad Electrode

The p-pad electrode 60 is located on the p-electrode 40. The p-pad electrode 60 contacts the p-electrode 40. The upper surface and lower surface of the p-pad electrode 60 each are substantially parallel to the X-Y plane. The p-pad electrode 60 is more proximate to the second side 10b than the first side 10a in a top-view. That is, the distance between the p-pad electrode 60 and the second side 10b is less than the distance between the p-pad electrode 60 and the first side 10a in a top-view.

The p-pad electrode 60 includes a first p-pad electrode region 60a and a second p-pad electrode region 60b. The first p-pad electrode region 60a extends in the first direction (the Y-direction) in a top-view. The second p-pad electrode region 60b extends from the first p-pad electrode region 60a in the second direction (the X-direction) in a top-view.

In the light-emitting element 100, the p-pad electrode 60 includes one first p-pad electrode region 60a and four second p-pad electrode regions 60b. The first p-electrode region 40a overlaps the first p-pad electrode region 60a in a top-view. The second p-electrode regions 40b overlap the second p-pad electrode regions 60b in a top-view. The number of the second p-pad electrode regions 60b is equal to the number of the second p-electrode regions 40b.

The p-pad electrode 60 includes, for example, at least one selected from the group consisting of Ti, Pt, Ni, and Au. The thickness of the p-pad electrode 60 is, for example, not less than 0.3 μm and not more than 1 μm.

### Protective Film

The light-emitting element 100 further includes a protective film 70. The protective film 70 is omissible. The protective film 70 is located on the substrate 10, the semiconductor structure body 20, the n-electrode 30, and the p-electrode 40. A portion of the n-pad electrode 50 is located on the protective film 70. A portion of the p-pad electrode 60 is located on the protective film 70. The protective film 70 contacts the substrate 10, the semiconductor structure body 20, the n-electrode 30, the p-electrode 40, the n-pad electrode 50, and the p-pad electrode 60.

The protective film 70 includes, for example, at least one selected from the group consisting of silicon oxide, silicon nitride, and silicon oxynitride. The thickness of the protective film 70 is, for example, not less than 0.5 μm and not more than 2 μm.

The first region 21a of the n-type semiconductor layer 21 includes a first part 21a1, a second part 21a2, a third part 21a3, and a fourth part 21a4. The first part 21al is positioned between the first n-electrode region 30a and the third p-electrode region 40c in a top-view. The second part 21a2 is positioned between the second n-electrode region 30b and the third p-electrode region 40c in a top-view. The third part 21a3 is positioned between the first p-electrode region 40a and the third n-electrode region 30c in a top-view. The fourth part 21a4 is positioned between the second p-electrode region 40b and the third n-electrode region 30c in a top-view.

In the light-emitting element 100, the first region 21a further includes a fifth part 21a5. The fifth part 21a5 is positioned between the third n-electrode region 30c and the third p-electrode region 40c in a top-view.

In the light-emitting element 100, the first region 21a further includes a sixth part 21a6 and a seventh part 21a7. The sixth part 21a6 is positioned between the second n-electrode region 30b and the fourth p-electrode region 40d in a top-view. The seventh part 21a7 is positioned between the third n-electrode region 30c and the fourth p-electrode region 40d in a top-view.

In the light-emitting element 100, the first region 21a further includes an outer perimeter part 21ax. The outer perimeter part 21ax is positioned between the first n-electrode region 30a and the first side 10a in a top-view. The first region 21a may not include the outer perimeter part 21ax.

In the light-emitting element 100, a first trench 25a is located in the first and second parts 21al and 21a2. In the light-emitting element 100, the first trench 25a is not located in the third part 21a3. The first trench 25a is recessed downward.

More specifically, in the light-emitting element 100, the first trench 25a is located in the first part 21a1, the second part 21a2, the fifth part 21a5, the sixth part 21a6, a portion of the seventh part 21a7, and a portion of the outer perimeter part 21ax. In the light-emitting element 100, the first trench 25a is not located in the third part 21a3, the fourth part 21a4, and a portion of the seventh part 21a7.

In the light-emitting element 100 as shown in FIG. 3, a depth D25a of the first trench 25a is less than a thickness T21a2 of the second part 21a2. That is, in the light-emitting element 100, the lower end of the first trench 25a does not reach the upper surface of the substrate 10. The depth D25a is, for example, not less than 0.5 μm and not more than 3 μm. The thickness T21a2 is, for example, not less than 3 μm and not more than 10 μm. Here, the thickness T21a2 of the second part 21a2 refers to the maximum thickness of the second part 21a2.

In the light-emitting element 100, a width W25a in the first direction (the Y-direction) of the first trench 25a is, for example, not less than 3% and not more than 25%, and favorably not less than 5% and not more than 15% of a width W21a2 in the first direction (the Y-direction) of the second part 21a2. The width W25a is, for example, not less than 1 μm and not more than 20 μm, favorably not less than 2 μm and not more than 10 μm, and more favorably not less than 2 μm and not more than 5 μm. The width W21a2 is, for example, not less than 10 μm and not more than 100 μm.

In the light-emitting element 100 as shown in FIG. 1, a width W30c in the first direction (the Y-direction) of the third n-electrode region 30c is less than a width W40c in the first direction (the Y-direction) of the third p-electrode region 40c. The width W30c is, for example, not less than 20 μm and not more than 80 μm, and favorably about 40 μm. The width W40c is, for example, not less than 30 μm and not more than 120 μm, and favorably about 60 μm.

### First Modification of First Embodiment

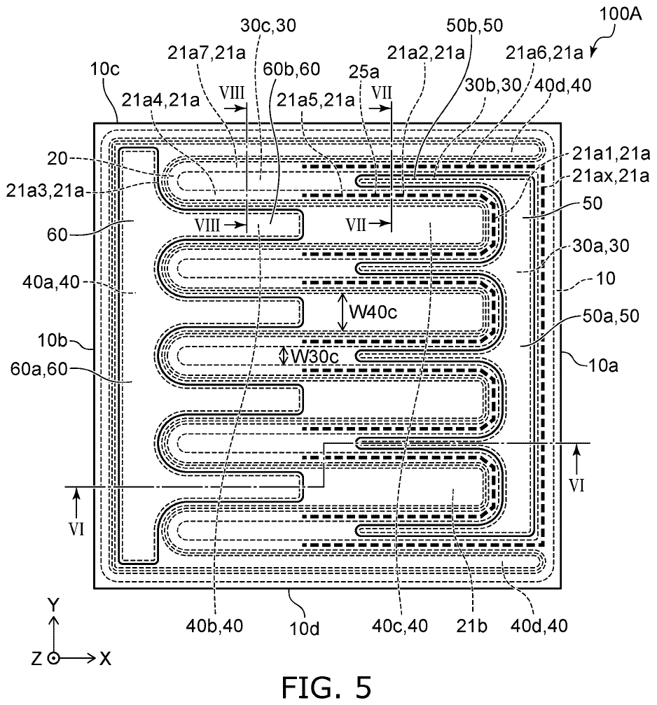

FIG. 5 is a plan view schematically showing a light-emitting element according to a first modification of the first embodiment.

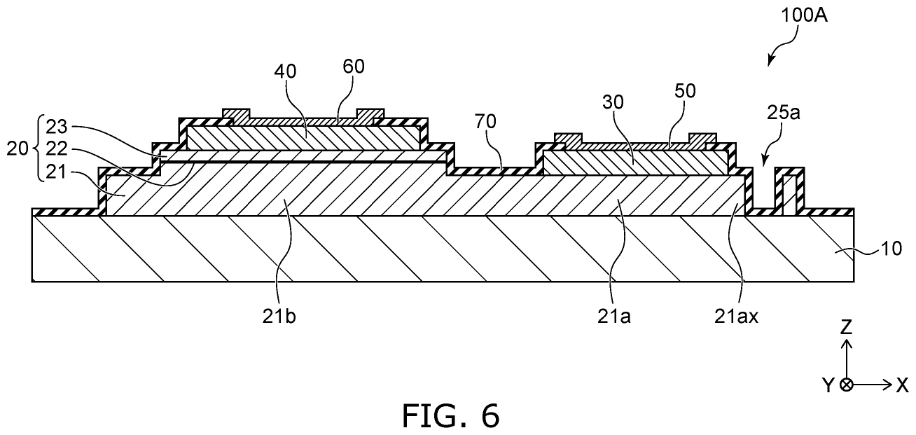

FIGS. 6 to 8 are cross-sectional views schematically showing the light-emitting element according to the first modification of the first embodiment.

FIG. 6 is a cross-sectional view along line VI-VI shown in FIG. 5.

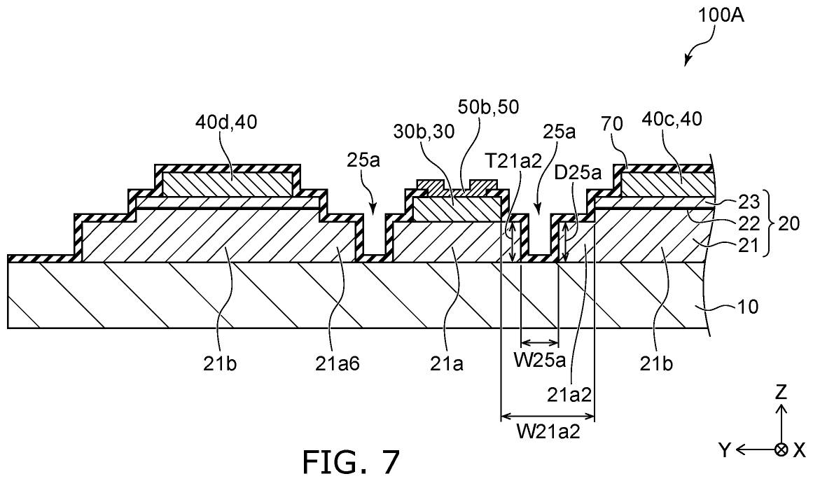

FIG. 7 is a cross-sectional view along line VII-VII shown in FIG. 5.

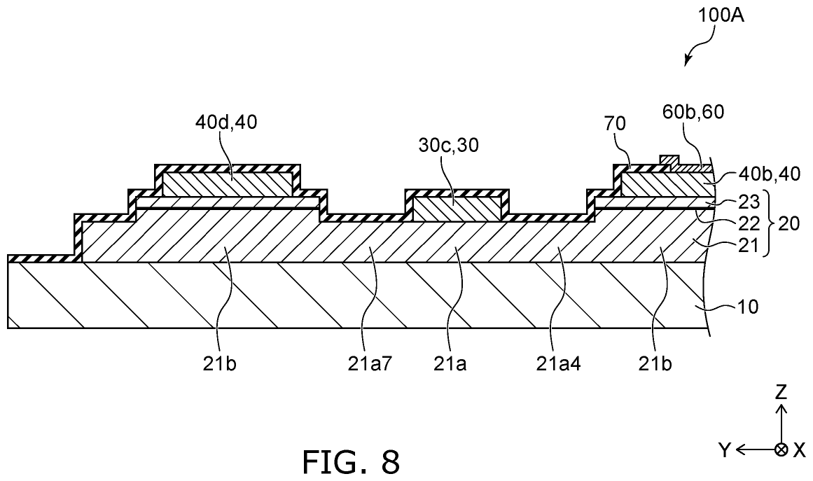

FIG. 8 is a cross-sectional view along line VIII-VIII shown in FIG. 5.

As shown in FIGS. 5 to 8, the light-emitting element 100A according to the first modification of the first embodiment is substantially the same as the light-emitting element 100 according to the first embodiment, other than the cross-sectional shape of the first trench 25a being different.

In the light-emitting element 100A, the depth D25a of the first trench 25a is equal to the thickness T21a2 of the second part 21a2. That is, in the light-emitting element 100A, the lower end of the first trench 25a reaches the upper surface of the substrate 10.

### Second Modification of First Embodiment

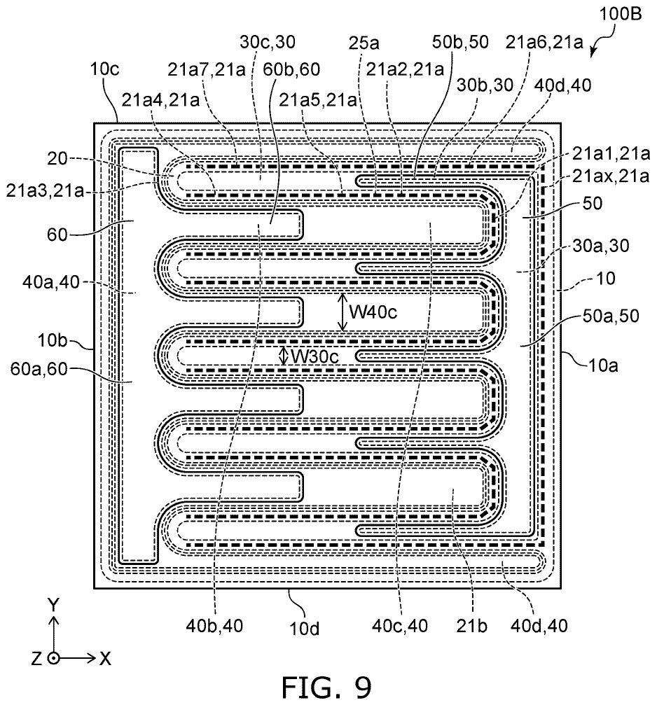

FIG. 9 is a plan view schematically showing a light-emitting element according to a second modification of the first embodiment.

As shown in FIG. 9, the light-emitting element 100B according to the second modification of the first embodiment is substantially the same as the light-emitting element 100 according to the first embodiment, other than the arrangement of the first trench 25a being different.

In the light-emitting element 100B, the first trench 25a is located in the first part 21a1, the second part 21a2, the fourth part 21a4, the fifth part 21a5, the sixth part 21a6, the seventh part 21a7, and the outer perimeter part 21ax. In the light-emitting element 100B, the first trench 25a is not located in the third part 21a3.

### Third Modification of First Embodiment

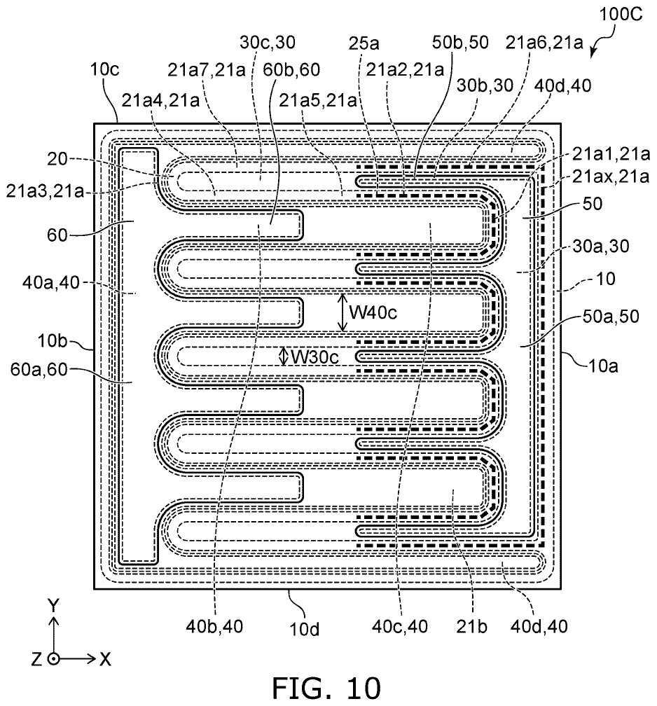

FIG. 10 is a plan view schematically showing a light-emitting element according to a third modification of the first embodiment.

As shown in FIG. 10, the light-emitting element 100C according to the third modification of the first embodiment is substantially the same as the light-emitting element 100 according to the first embodiment, other than the arrangement of the first trench 25a being different.

In the light-emitting element 100C, the first trench 25a is located in the first part 21a1, the second part 21a2, the sixth part 21a6, and the outer perimeter part 21ax. In the light-emitting element 100C, the first trench 25a is not located in the third part 21a3, the fourth part 21a4, the fifth part 21a5, and the seventh part 21a7.

### Fourth Modification of First Embodiment

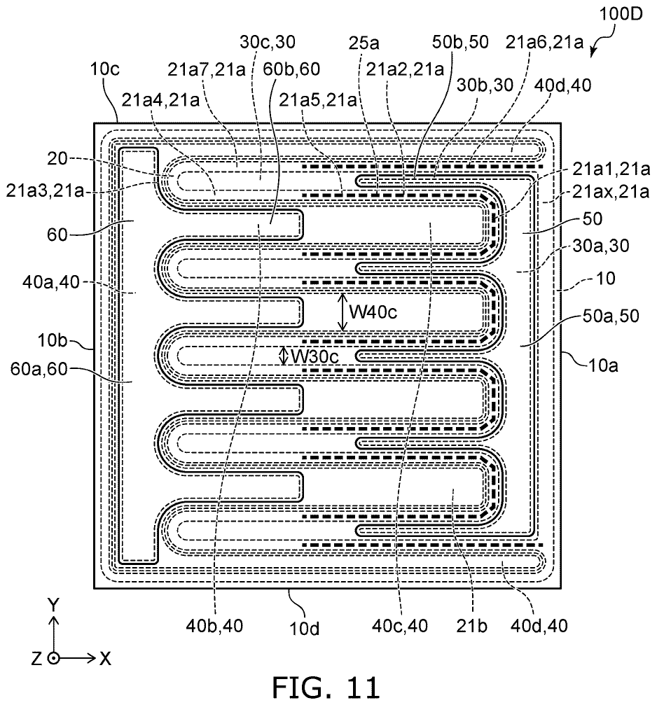

FIG. 11 is a plan view schematically showing a light-emitting element according to a fourth modification of the first embodiment.

As shown in FIG. 11, the light-emitting element 100D according to the fourth modification of the first embodiment is substantially the same as the light-emitting element 100 according to the first embodiment, other than the arrangement of the first trench 25a being different.

In the light-emitting element 100D, the first trench 25a is located in the first part 21a1, the second part 21a2, the fifth part 21a5, the sixth part 21a6, and a portion of the seventh part 21a7. In the light-emitting element 100D, the first trench 25a is not located in the third part 21a3, the fourth part 21a4, a portion of the seventh part 21a7, and the outer perimeter part 21ax.

### Fifth Modification of First Embodiment

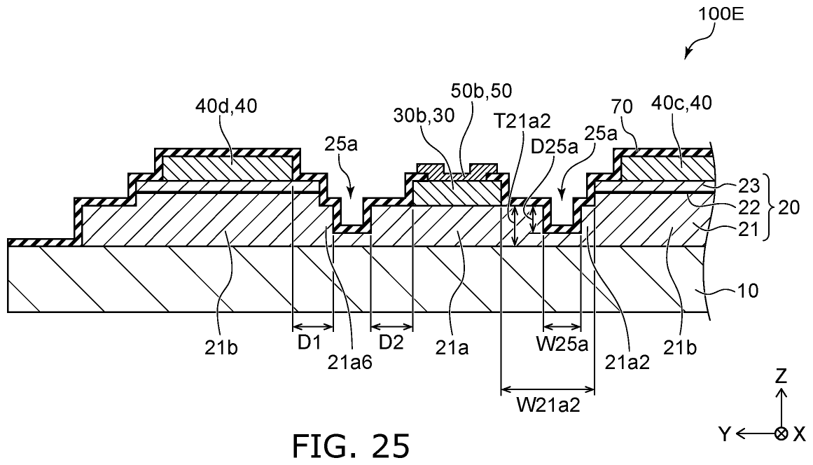

FIG. 25 is a cross-sectional view schematically showing a light-emitting element according to a fifth modification of the first embodiment.

As shown in FIG. 25, the light-emitting element 100E according to the fifth modification of the first embodiment is substantially the same as the light-emitting element 100 according to the first embodiment, other than the arrangement of the first trench 25a being different.

In the light-emitting element 100E, a distance D1 between the first trench 25a and the p-electrode 40 is less than a distance D2 between the first trench 25a and the n-electrode 30. Thus, it is favorable for the distance D1 between the first trench 25a and the p-electrode 40 to be less than the distance D2 between the first trench 25a and the n-electrode 30 when viewed in cross-section. By locating the first trench 25a more proximate to the active layer 22 than the n-electrode 30, the first trench 25a makes it difficult for the light from the active layer 22 to travel toward the n-electrode 30, and so optical absorption by the n-electrode 30 can be reduced, and the output can be improved.

### Second Embodiment

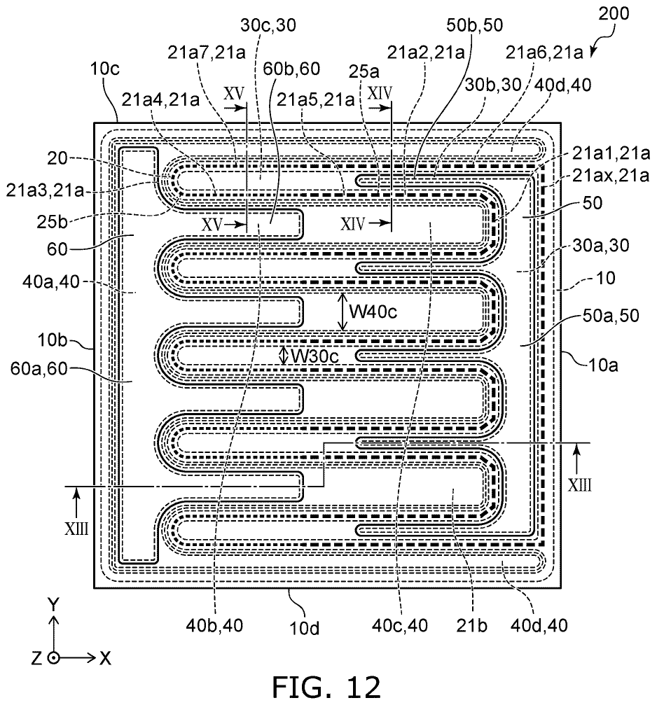

FIG. 12 is a plan view schematically showing a light-emitting element according to a second embodiment.

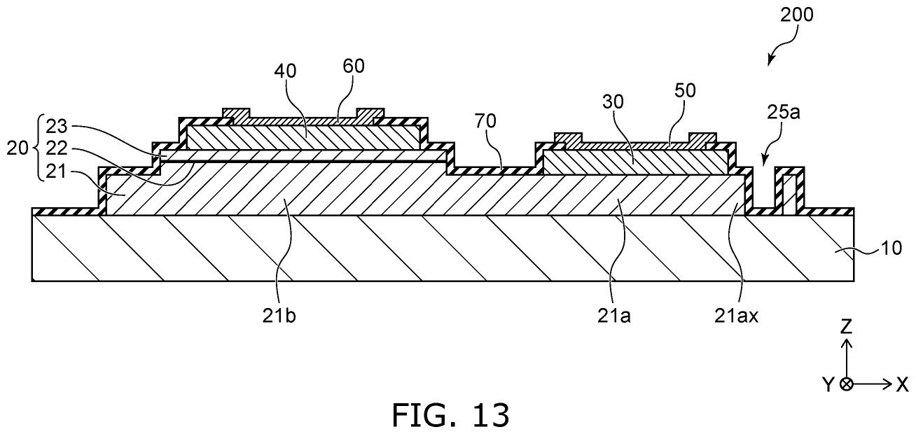

FIGS. 13 to 15 are cross-sectional views schematically showing the light-emitting element according to the second embodiment.

FIG. 13 is a cross-sectional view along line XIII-XIII shown in FIG. 12.

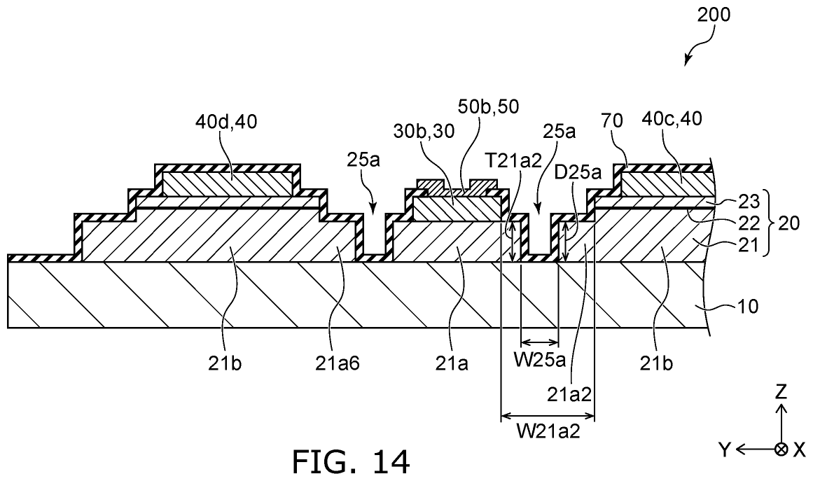

FIG. 14 is a cross-sectional view along line XIV-XIV shown in FIG. 12.

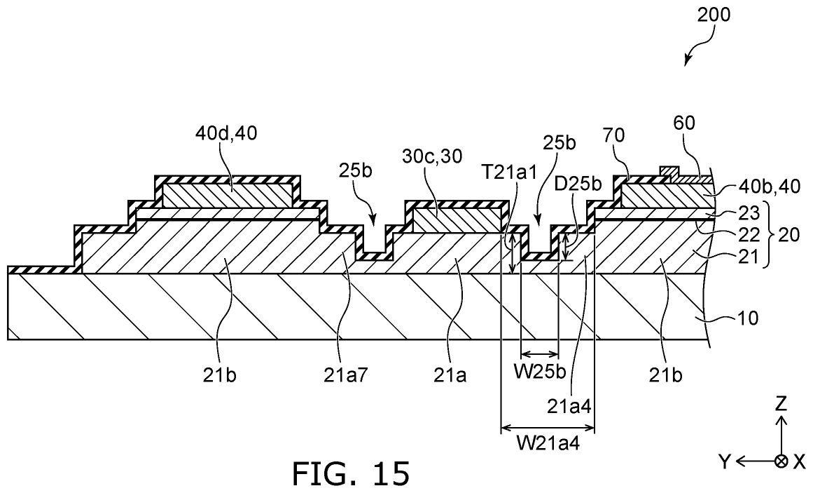

FIG. 15 is a cross-sectional view along line XV-XV shown in FIG. 12.

As shown in FIGS. 12 to 15, the light-emitting element 200 according to the second embodiment is substantially the same as the light-emitting element 100 according to the first embodiment, other than a second trench 25b being formed in addition to the first trench 25a.

In the light-emitting element 200, the first trench 25a is located in the first and second parts 21al and 21a2. In the light-emitting element 200, the second trench 25b is located in at least one of the third part 21a3 or the fourth part 21a4. The first trench 25a and the second trench 25b each are recessed downward.

More specifically, in the light-emitting element 200, the first trench 25a is located in the first part 21al, the second part 21a2, the fifth part 21a5, the sixth part 21a6, a portion of the seventh part 21a7, and the outer perimeter part 21ax. In the light-emitting element 200, the second trench 25b is located in the third part 21a3, the fourth part 21a4, and a portion of the seventh part 21a7. The first trench 25a and the second trench 25b are continuous in a top-view.

In the light-emitting element 200, a depth D25b of the second trench 25b is less than the depth D25a of the first trench 25a. In the light-emitting element 200, the depth D25a of the first trench 25a is equal to the thickness T21a2 of the second part 21a2. That is, in the light-emitting element 200, the lower end of the first trench 25a reaches the upper surface of the substrate 10. In the light-emitting element 200, the depth D25b of the second trench 25b is less than the thickness T21a2 of the second part 21a2. That is, in the light-emitting element 200, the lower end of the second trench 25b does not reach the upper surface of the substrate 10. The depth D25a of the first trench 25a may be less than the thickness T21a2 of the second part 21a2. That is, the lower end of the first trench 25a may not reach the upper surface of the substrate 10. The depth D25a is, for example, not less than 3 μm and not more than 10 μm. The depth D25b is, for example, not less than 0.5 μm and not more than 3 μm. The thickness T21a2 is, for example, not less than 3 μm and not more than 10 μm.

In the light-emitting element 200, a width W25b in the first direction (the Y-direction) of the second trench 25b is equal to the width W25a in the first direction (the Y-direction) of the first trench 25a. The width W25a in the first direction (the Y-direction) of the first trench 25a is, for example, not less than 3% and not more than 25%, and favorably not less than 5% and not more than 15% of the width W21a2 in the first direction (the Y-direction) of the second part 21a2. The width W25b in the first direction (the Y-direction) of the second trench 25b is, for example, not less than 3% and not more than 25%, and favorably not less than 5% and not more than 15% of a width W21a4 in the first direction (the Y-direction) of the fourth part 21a4. The width W25a and the width W25b are, for example, not less than 1 μm and not more than 20 μm, favorably not less than 2 μm and not more than 10 μm, and more favorably not less than 2 μm and not more than 5 μm. The width W21a2 and the width W21a4 are, for example, not less than 10 μm and not more than 100 μm.

In the light-emitting element 200, the width W30c in the first direction (the Y-direction) of the third n-electrode region 30c is less than the width W40c in the first direction (the Y-direction) of the third p-electrode region 40c. The width W30c is, for example, not less than 20 μm and not more than 80 μm, and favorably about 40 μm. The width W40c is, for example, not less than 30 μm and not more than 120 μm, and favorably about 60 μm.

### First Modification of Second Embodiment

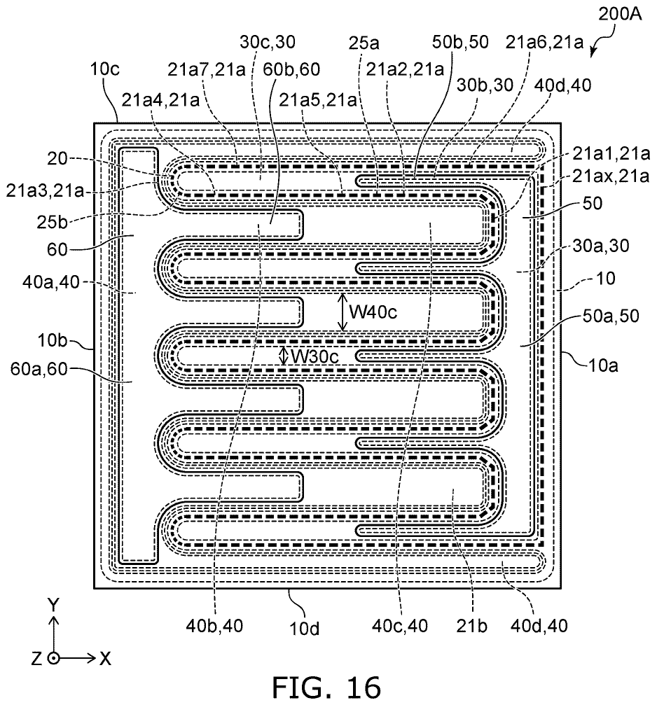

FIG. 16 is a plan view schematically showing a light-emitting element according to a first modification of the second embodiment.

As shown in FIG. 16, the light-emitting element 200A according to the first modification of the second embodiment is substantially the same as the light-emitting element 200 according to the second embodiment, other than the arrangements of the first and second trenches 25a and 25b being different.

In the light-emitting element 200A, the first trench 25a is located in the first part 21a1, the second part 21a2, the fourth part 21a4, the fifth part 21a5, the sixth part 21a6, the seventh part 21a7, and the entire outer perimeter part 21ax. In the light-emitting element 200A, the second trench 25b is located in the third part 21a3.

### Second Modification of Second Embodiment

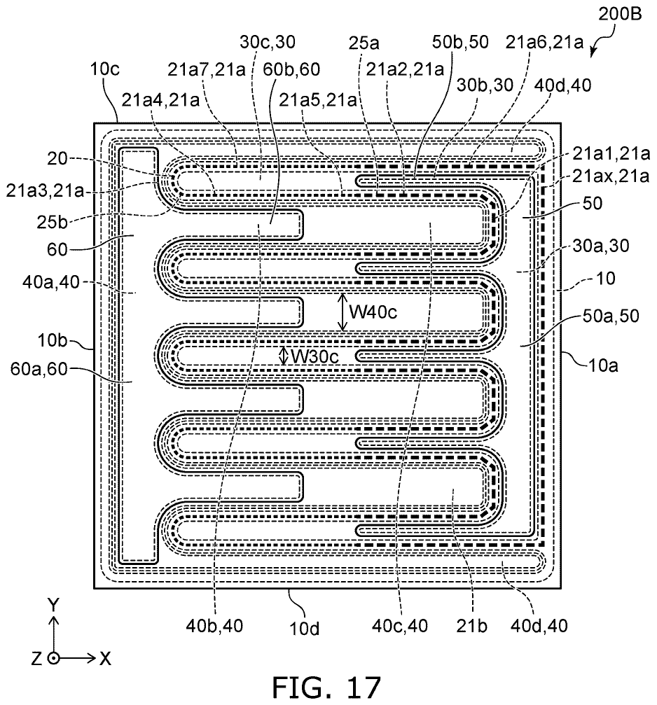

FIG. 17 is a plan view schematically showing a light-emitting element according to a second modification of the second embodiment.

As shown in FIG. 17, the light-emitting element 200B according to the second modification of the second embodiment is substantially the same as the light-emitting element 200 according to the second embodiment, other than the arrangements of the first and second trenches 25a and 25b being different.

In the light-emitting element 200B, the first trench 25a is located in the first part 21a1, the second part 21a2, the sixth part 21a6, and the outer perimeter part 21ax. In the light-emitting element 200B, the second trench 25b is located in the third part 21a3, the fourth part 21a4, the fifth part 21a5, and the seventh part 21a7.

### Third Modification of Second Embodiment

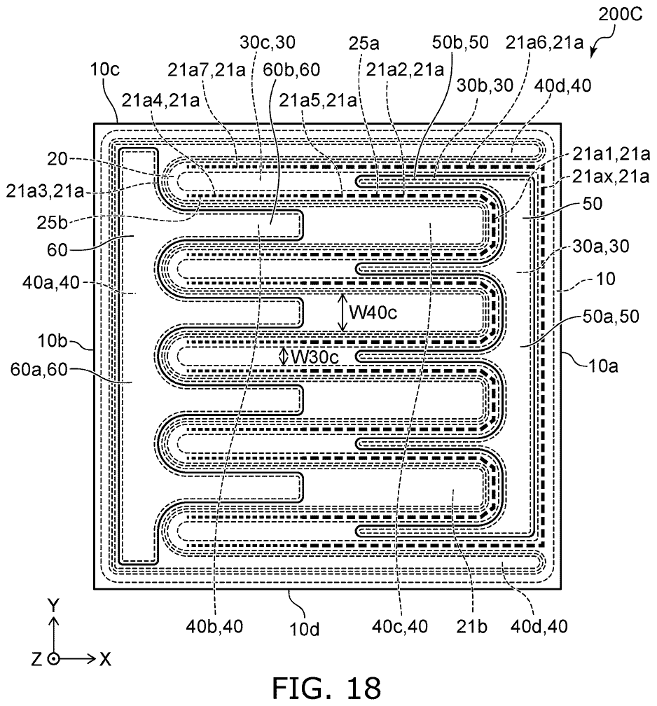

FIG. 18 is a plan view schematically showing a light-emitting element according to a third modification of the second embodiment.

As shown in FIG. 18, the light-emitting element 200C according to the third modification of the second embodiment is substantially the same as the light-emitting element 200 according to the second embodiment, other than the arrangements of the first and second trenches 25a and 25b being different.

In the light-emitting element 200C, the first trench 25a is located in the first part 21a1, the second part 21a2, the fifth part 21a5, the sixth part 21a6, a portion of the seventh part 21a7, and the outer perimeter part 21ax. In the light-emitting element 200C, the second trench 25b is located in the fourth part 21a4 and a portion of the seventh part 21a7. In the light-emitting element 200C, neither the first trench 25a nor the second trench 25b is located in the third part 21a3.

### Fourth Modification of Second Embodiment

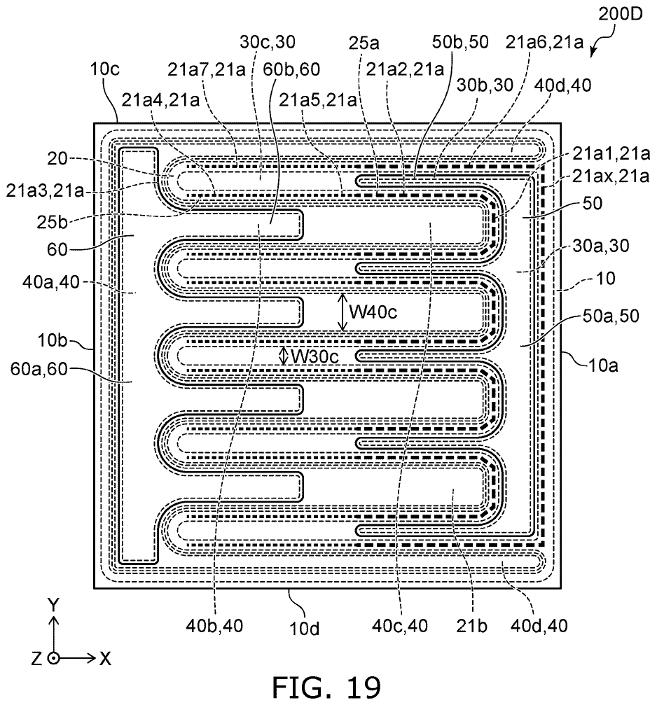

FIG. 19 is a plan view schematically showing a light-emitting element according to a fourth modification of the second embodiment.

As shown in FIG. 19, the light-emitting element 200D according to the fourth modification of the second embodiment is substantially the same as the light-emitting element 200 according to the second embodiment, other than the arrangements of the first and second trenches 25a and 25b being different.

In the light-emitting element 200D, the first trench 25a is located in the first part 21a1, the second part 21a2, the sixth part 21a6, and the outer perimeter part 21ax. In the light-emitting element 200D, the second trench 25b is located in the fourth part 21a4, the fifth part 21a5, and the seventh part 21a7. In the light-emitting element 200D, neither the first trench 25a nor the second trench 25b is located in the third part 21a3.

### Fifth Modification of Second Embodiment

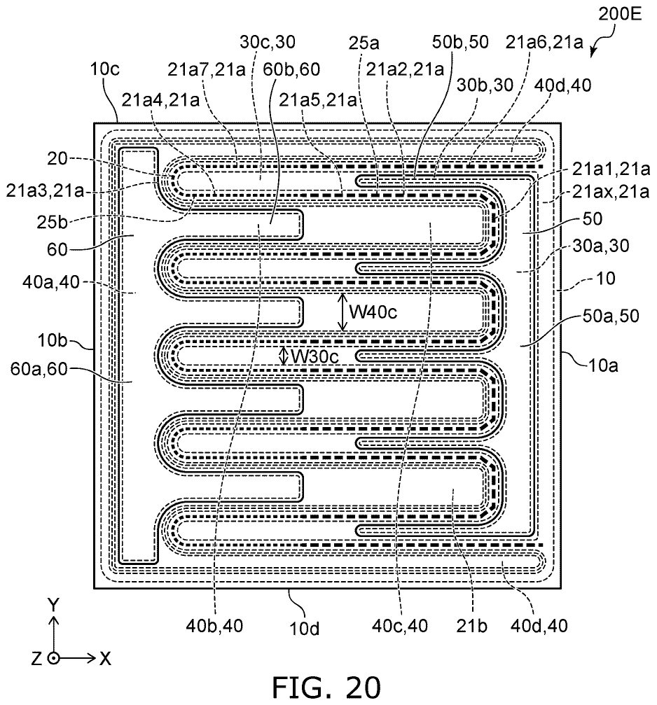

FIG. 20 is a plan view schematically showing a light-emitting element according to a fifth modification of the second embodiment.

As shown in FIG. 20, the light-emitting element 200E according to the first modification of the second embodiment is substantially the same as the light-emitting element 200 according to the second embodiment, other than the arrangements of the first and second trenches 25a and 25b being different.

In the light-emitting element 200E, the first trench 25a is located in the first part 21a1, the second part 21a2, the fifth part 21a5, the sixth part 21a6, and a portion of the seventh part 21a7. In the light-emitting element 200E, the second trench 25b is located in the third part 21a3, the fourth part 21a4, and a portion of the seventh part 21a7. In the light-emitting element 200E, neither the first trench 25a nor the second trench 25b is located in the outer perimeter part 21ax. In the light-emitting element 200E, the second trench 25b may be located in the outer perimeter part 21ax.

### Third Embodiment

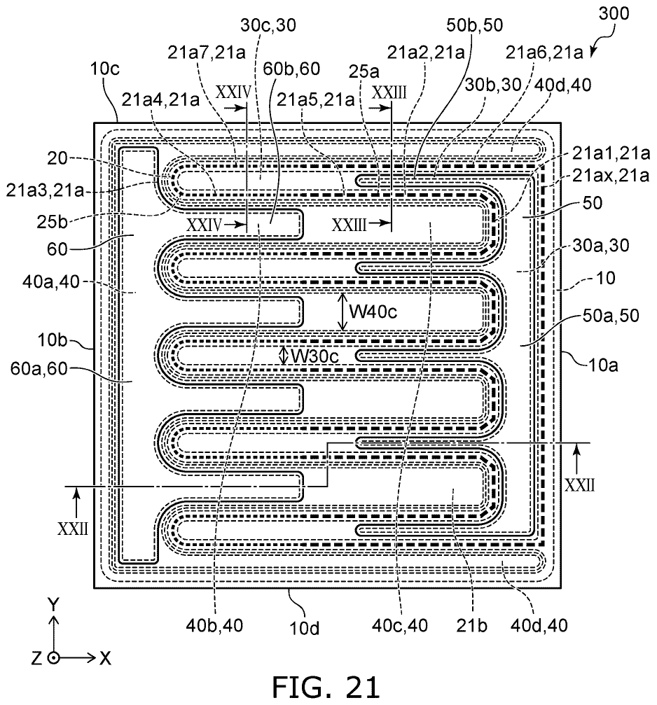

FIG. 21 is a plan view schematically showing a light-emitting element according to a third embodiment.

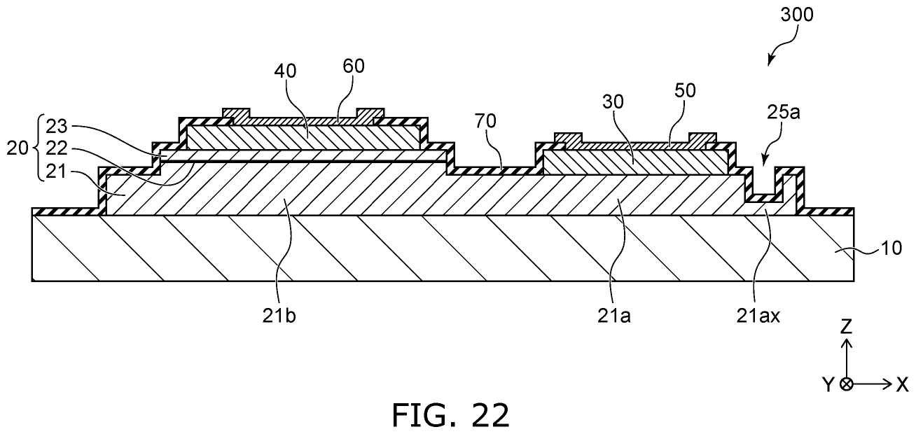

FIGS. 22 to 24 are cross-sectional views schematically showing the light-emitting element according to the third embodiment.

FIG. 22 is a cross-sectional view along line XXII-XXII shown in FIG. 21.

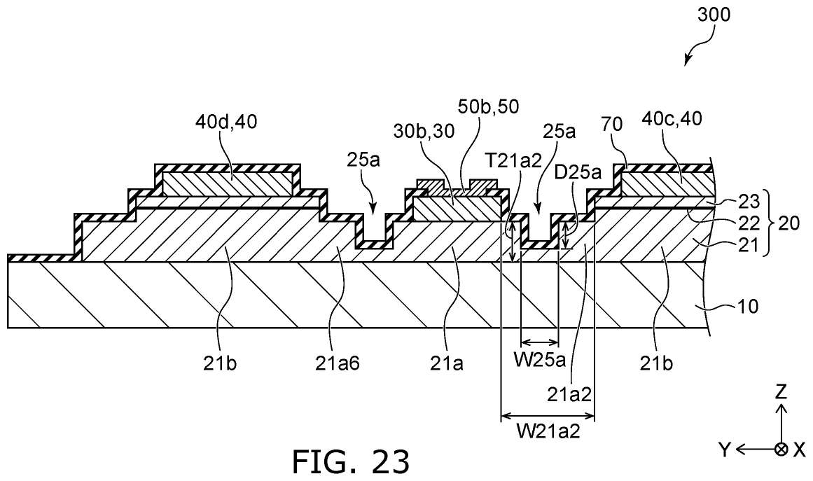

FIG. 23 is a cross-sectional view along line XXIII-XXIII shown in FIG. 21.

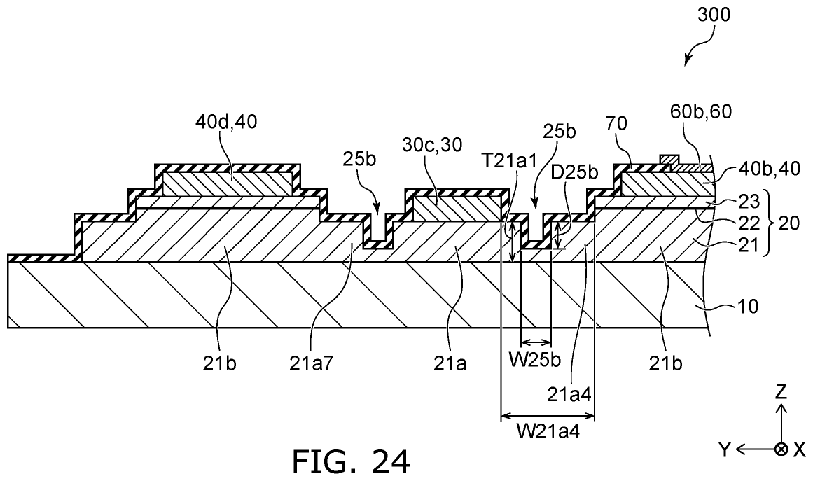

FIG. 24 is a cross-sectional view along line XXIV-XXIV shown in FIG. 21.

As shown in FIGS. 21 to 24, the light-emitting element 300 according to the third embodiment is substantially the same as the light-emitting element 100 according to the first embodiment, other than the second trench 25b being formed in addition to the first trench 25a.

In the light-emitting element 300, the first trench 25a is located in the first and second parts 21al and 21a2. In the light-emitting element 300, the second trench 25b is located in at least one of the third part 21a3 or the fourth part 21a4. The first trench 25a and the second trench 25b each are recessed downward.

More specifically, in the light-emitting element 300, the first trench 25a is located in the first part 21a1, the second part 21a2, the fifth part 21a5, the sixth part 21a6, a portion of the seventh part 21a7, and the outer perimeter part 21ax. In the light-emitting element 300, the second trench 25b is located in the third part 21a3, the fourth part 21a4, and a portion of the seventh part 21a7. The positions of the first and second trenches 25a and 25b in the light-emitting element 300 according to the third embodiment may be the same as those of the first to fifth modifications of the second embodiment above.

In the light-emitting element 300, the depth D25b of the second trench 25b is equal to the depth D25a of the first trench 25a. In the light-emitting element 300, the depth D25a of the first trench 25a and the depth D25b of the second trench 25b are less than the thickness T21a2 of the second part 21a2. That is, in the light-emitting element 300, the lower end of the first trench 25a and the lower end of the second trench 25b do not reach the upper surface of the substrate 10. The depth D25a of the first trench 25a and the depth D25b of the second trench 25b may be equal to the thickness T21a2 of the second part 21a2. That is, the lower end of the first trench 25a and the lower end of the second trench 25b may reach the upper surface of the substrate 10. The depth D25a and the depth D25b are, for example, not less than 0.5 μm and not more than 3 μm. The thickness T21a2 is, for example, not less than 3 μm and not more than 10 μm.

In the light-emitting element 300, the width W25b in the first direction (the Y-direction) of the second trench 25b is less than the width W25a in the first direction (the Y-direction) of the first trench 25a. The width W25a in the first direction (the Y-direction) of the first trench 25a is, for example, not less than 3% and not more than 25%, and favorably not less than 5% and not more than 15% of a width W21al in the first direction (the Y-direction) of the second part 21a2. The width W25b in the first direction (the Y-direction) of the second trench 25b is, for example, not less than 3% and not more than 25%, and favorably not less than 5% and not more than 15% of the width W21a4 in the first direction (the Y-direction) of the fourth part 21a4. The width W25a and the width W25b are, for example, not less than 1 μm and not more than 20 μm, favorably not less than 2 μm and not more than 10 μm, and more favorably not less than 2 μm and not more than 5 μm. The width W21a2 and the width W21a4 are, for example, not less than 10 μm and not more than 100 μm.

In the light-emitting element 300, the width W30c in the first direction (the Y-direction) of the third n-electrode region 30c is less than the width W40c in the first direction (the Y-direction) of the third p-electrode region 40c. The width W30c is, for example, not less than 20 μm and not more than 80 μm, and favorably about 40 μm. The width W40c is, for example, not less than 30 μm and not more than 120 μm, and favorably about 60 μm.

Effects of the light-emitting elements according to the first to third embodiments will now be described.

In light-emitting elements, there are cases in which current concentrates at the periphery of the n-pad electrode, and there is a risk that the reliability of the light-emitting element may degrade. A technique to solve this problem may be considered in which a trench is formed in the semiconductor structure body at the periphery of the n-pad electrode to increase the current path at the periphery of the n-pad electrode (that is, to make it difficult for the current to flow). When, however, trenches surround the entire n-electrode, there is a risk that the forward voltage may increase.

In contrast, in the light-emitting element according to the first embodiment, the first trench 25a is located in the first and second parts 21al and 21a2, and the first trench 25a is not located in the third part 21a3. As a result, an increase of the forward voltage can be suppressed while reducing the current concentration at the periphery of the n-pad electrode 50. Also, the first trench 25a makes it difficult for the light from the active layer 22 to travel toward the n-electrode 30, and so optical absorption by the n-electrode 30 can be reduced, and the output can be improved.

In the light-emitting element according to the second embodiment, the first trench 25a is located in the first and second parts 21al and 21a2, and the second trench 25b, which is shallower than the first trench 25a, is located in at least one of the third part 21a3 or the fourth part 21a4. As a result, an increase of the forward voltage can be suppressed while reducing the current concentration at the periphery of the n-pad electrode 50. Also, the first trench 25a makes it difficult for the light from the active layer 22 to travel toward the n-electrode 30, and so optical absorption by the n-electrode 30 can be reduced, and the output can be improved.

In the light-emitting element according to the third embodiment, the first trench 25a is located in the first and second parts 21al and 21a2, and the second trench 25b, which is narrower than the first trench 25a, is located in at least one of the third part 21a3 or the fourth part 21a4. As a result, an increase of the forward voltage can be suppressed while reducing the current concentration at the periphery of the n-pad electrode 50. Also, the first trench 25a makes it difficult for the light from the active layer 22 to travel toward the n-electrode 30, and so optical absorption by the n-electrode 30 can be reduced, and the output can be improved.

In the light-emitting element according to the first embodiment, the first trench 25a is located in the fourth part 21a4, and so the current concentration at the periphery of the n-pad electrode 50 can be further reduced compared to when the first trench 25a is located in the fourth part 21a4.

In the light-emitting element according to the first embodiment, the first trench 25a is not located in the fourth part 21a4, and so an increase of the forward voltage can be suppressed compared to when the first trench 25a is located in the fourth part 21a4.

In the light-emitting elements according to the second and third embodiments, the second trench 25b is located in the fourth part 21a4, and neither the first trench 25a nor the second trench 25b is located in the third part 21a3. As a result, an increase of the forward voltage can be suppressed.

In the light-emitting elements according to the second and third embodiments, the second trench 25b is located in the third part 21a3, and the first trench 25a is located in the fourth part 21a4. As a result, an increase of the forward voltage can be suppressed compared to when the first trench 25a is located in the third and fourth parts 21a3 and 21a4.

In the light-emitting elements according to the second and third embodiments, the second trench 25b is located in the third and fourth parts 21a3 and 21a4, and so an increase of the forward voltage can be suppressed compared to when the first trench 25a is located in the third and fourth parts 21a3 and 21a4. Also, compared to when the first trench 25a and the second trench 25b are not located in the third and fourth parts 21a3 and 21a4, optical absorption by the n-electrode 30 can be reduced, and the output can be improved.

In the light-emitting elements according to the first to third embodiments, the first trench 25a is located in the fifth part 21a5, and so the current concentration at the periphery of the n-pad electrode 50 can be further reduced. Also, compared to when the first trench 25a and the second trench 25b are not located in the fifth part 21a5, optical absorption by the n-electrode 30 can be reduced, and the output can be improved.

In the light-emitting elements according to the first to third embodiments, the first trench 25a is not located in the fifth part 21a5, and so an increase of the forward voltage can be suppressed compared to when the first trench 25a is located in the fifth part 21a5.

In the light-emitting elements according to the second and third embodiments, the second trench 25b is located in the fifth part 21a5, and so an increase of the forward voltage can be suppressed compared to when the first trench 25a is located in the fifth part 21a5. Also, compared to when the first trench 25a and the second trench 25b are not located in the fifth part 21a5, optical absorption by the n-electrode 30 can be reduced, and the output can be improved.

In the light-emitting elements according to the first to third embodiments, the first trench 25a is located in the outer perimeter part 21ax, and so compared to when the first trench 25a is not located in the outer perimeter part 21ax, optical absorption by the n-electrode 30 can be reduced, and the output can be improved.

In the light-emitting elements according to the first to third embodiments, the first trench 25a is not located in the outer perimeter part 21ax, and so compared to when the first trench 25a is located in the outer perimeter part 21ax, more of the n-type semiconductor layer 21 can remain, and so an increase of the forward voltage can be suppressed.

In the light-emitting elements according to the first to third embodiments, the width W25a of the first trench 25a is not less than 3% and not more than 25% of the width W21a2 of the second part 21a2, and so more of the n-type semiconductor layer 21 can remain, an increase of the forward voltage can be suppressed, optical absorption by the n-electrode 30 can be reduced, and the output can be improved.

In the light-emitting elements according to the first to third embodiments, the depth D25a of the first trench 25a is less than the thickness T21a2 of the second part 21a2, and so compared to when the depth D25a is equal to the thickness T21a2, more of the n-type semiconductor layer 21 can remain, and so an increase of the forward voltage can be suppressed.

In the light-emitting elements according to the first to third embodiments, the depth D25a of the first trench 25a is equal to the thickness T21a2 of the second part 21a2, and so optical absorption by the n-electrode 30 can be reduced, and the output can be improved.

In the light-emitting elements according to the first to third embodiments, the width W30c of the third n-electrode region 30c is less than the width W40c of the third p-electrode region 40c, and so optical absorption by the third n-electrode region 30c can be reduced, and the output can be improved.

The trench may be taken to be only a linear trench, only a broken or dotted trench, or a combination of linear and broken or dotted trenches. A trench that is positioned on two or more lines may be formed.

### Example 1 and Reference Examples 1 to 3

Light-emitting elements of Example 1 and Reference Examples 1 to 3 were made from one wafer, and a forward voltage Vf and an output Po when a current of 350 mA was applied to the light-emitting elements were measured for the light-emitting elements of Example 1 and Reference Examples 1 to 3. For the light-emitting elements of Example 1 and Reference Examples 1 to 3, the luminance distribution was observed for each light-emitting element in a top-view, and the presence of a location at which current concentration occurred at the periphery of the n-pad electrode was determined. The results are shown in Table 1.

### Example 1

The light-emitting element of Example 1 corresponds to the light-emitting element 100B according to the second modification of the first embodiment shown in FIG. 9. In the light-emitting element of Example 1, the first trench 25a was located in the first part 21a1, the second part 21a2, the fourth part 21a4, the fifth part 21a5, the sixth part 21a6, the seventh part 21a7, and the outer perimeter part 21ax shown in FIG. 9, and the first trench 25a was not located in the third part 21a3. That is, in the light-emitting element of Example 1, the first trench 25a was located in the periphery of the n-electrode 30 other than the third part 21a3.

### Reference Example 1

In the light-emitting element of Reference Example 1, the first trench 25a was not located in any of the first part 21al, the second part 21a2, the third part 21a3, the fourth part 21a4, the fifth part 21a5, the sixth part 21a6, the seventh part 21a7, and the outer perimeter part 21ax shown in FIG. 9. That is, in the light-emitting element of Reference Example 1, the first trench 25a was not located in the periphery of the n-electrode 30.

### Reference Example 2

In the light-emitting element of Reference Example 2, the first trench 25a was located in each of the first part 21a1, the second part 21a2, the third part 21a3, the fourth part 21a4, the fifth part 21a5, the sixth part 21a6, the seventh part 21a7, and the outer perimeter part 21ax shown in FIG. 9. That is, in the light-emitting element of Reference Example 2, the first trench 25a was located in all parts of the periphery of the n-electrode 30.

### Reference Example 3

In the light-emitting element of Reference Example 3, the first trench 25a was located in the second part 21a2, the third part 21a3, the fourth part 21a4, the fifth part 21a5, the sixth part 21a6, the seventh part 21a7, and the outer perimeter part 21ax shown in FIG. 9, and the first trench 25a was not located in the first part 21al. That is, in the light-emitting element of Reference Example 3, the first trench 25a was located in the periphery of the n-electrode 30 other than the first part 21a1.

In Example 1 and Reference Examples 1 to 3, the shape of the substrate 10 in a top-view was a square in which each side was 1,000 μm. In Example 1 and Reference Examples 2 and 3, the width W25a of the first trench 25a was 9 μm, and the depth D25a of the first trench 25a was 2 μm. In Example 1 and Reference Examples 1 to 3, the width W21a2 of the second part 21a2 was about 22 μm, and the thickness T21a2 of the second part 21a2 was about 6 μm.

TABLE 1

| | | | Current |
|---|---|---|---|
| | Vf[V] | Po[mW] | concentration |
| Example 1 | 5.31 | 196.1 | No |
| Reference Example 1 | 5.15 | 184.4 | Yes |
| Reference Example 2 | 6.35 | 198.4 | No |
| Reference Example 3 | 5.32 | 194.7 | Yes |

As shown in Table 1, in the light-emitting element of Reference Example 1, the first trench 25a was not located in the periphery of the n-electrode 30, and so the forward voltage Vf was low, but the output Po was low, and there was a location at which current concentration occurred. In the light-emitting element of Reference Example 2, the first trench 25a was located in all parts of the periphery of the n-electrode 30, and so the output Po was high, and there were no locations at which current concentration occurred, but the forward voltage Vf was high. In the light-emitting element of Reference Example 3, the first trench 25a was located in the periphery of the n-electrode 30 other than the first part 21a1, and so the forward voltage Vf was not high, but the output Po also was not high, and there was a location at which current concentration occurred at the periphery of the n-pad electrode. In contrast, in the light-emitting element of Example 1, the first trench 25a was located in the periphery of the n-electrode 30 other than the third part 21a3, and so the forward voltage Vf was not high, the output Po was high, and there was no location at which current concentration occurred in the periphery of the n-pad electrode. That is, it is considered that the light-emitting element of Example 1 had a higher reliability than the light-emitting elements of Reference Examples 1 to 3.

### Examples 2 to 7 and Reference Example 4

Light-emitting elements of Examples 2 to 7 and Reference Example 4 were made from a different wafer from the wafer from which Example 1 and Reference Examples 1 to 3 were made, and the forward voltage Vf and the output Po when a current of 350 mA was applied to the light-emitting elements were measured for the light-emitting elements of Examples 2 to 7 and Reference Example 4. The results are shown in Table 2. For Examples 2 to 7, the changes of the forward voltage Vf and the output Po are shown for when the width W25a of the first trench 25a was changed and when the ratio of the width W25a of the first trench 25a to the width W21a2 of the second part 21a2 was changed accordingly.

### Examples 2 to 7

The light-emitting elements of Examples 2 to 7 correspond to the light-emitting element 100B according to the second modification of the first embodiment shown in FIG. 9. In the light-emitting elements of Examples 2 to 7, the first trench 25a was located in the first part 21a1, the second part 21a2, the fourth part 21a4, the fifth part 21a5, the sixth part 21a6, the seventh part 21a7, and the outer perimeter part 21ax shown in FIG. 9, and the first trench 25a was not located in the third part 21a3. That is, in the light-emitting elements of Examples 2 to 7, the first trench 25a was located in the periphery of the n-electrode 30 other than the third part 21a3.

### Reference Example 4

In the light-emitting element of Reference Example 4, the first trench 25a was not located in any of the first part 21a1, the second part 21a2, the third part 21a3, the fourth part 21a4, the fifth part 21a5, the sixth part 21a6, the seventh part 21a7, and the outer perimeter part 21ax shown in FIG. 9. That is, in the light-emitting element of Reference Example 4, the first trench 25a was not located in the periphery of the n-electrode 30.

In Examples 2 to 7 and Reference Example 4, the shape of the substrate 10 in a top-view was a square in which each side was 1,000 μm. In Examples 2 to 7 as shown in Table 2, the width W25a of the first trench 25a was 1.5 to 9.5 μm, and the depth D25a of the first trench 25a was 2 μm. In Examples 2 to 7 and Reference Example 4, the width W21a2 of the second part 21a2 was about 22 μm, and the thickness T21a2 of the second part 21a2 was about 6 μm. In Examples 2 to 7 as shown in Table 2, the ratio of the width W25a of the first trench 25a to the width W21a2 of the second part 21a2 was 6.82 to 43.18%.

TABLE 2

| | W25a[μm] | Vf[V] | Po[mW] | W25a/W21a2[%] |
|---|---|---|---|---|
| Reference | — | 5.11 | 180.6 | — |
| Example 4 | | | | |
| Example 2 | 1.5 | 5.21 | 198.9 | 6.82 |
| Example 3 | 2.5 | 5.24 | 198.6 | 11.36 |
| Example 4 | 3.5 | 5.26 | 198.5 | 15.91 |
| Example 5 | 4.5 | 5.28 | 199.0 | 20.45 |
| Example 6 | 5.5 | 5.29 | 198.9 | 25 |
| Example 7 | 9.5 | 6.40 | 198.2 | 43.18 |

In the light-emitting element of Reference Example 4 as shown in Table 2, the first trench 25a was not located in the periphery of the n-electrode 30, and so the forward voltage Vf was low, but the output Po was low. In contrast, in the light-emitting elements of Examples 2 to 7, the first trench 25a was located in the periphery of the n-electrode 30 other than the third part 21a3, and so the forward voltage Vf was not high, and the output Po was high. That is, it is considered that the light-emitting elements of Examples 2 to 7 had higher reliability than the light-emitting element of Reference Example 4. The light-emitting elements of Examples 2 to 7 suggest that the forward voltage Vf increased as the ratio of the width W25a of the first trench 25a to the width W21a2 of the second part 21a2 increased. This suggests that if the width W25a of the first trench 25a is not less than 5% and not more than 25% of the width W21a2 of the second part 21a2, the output Po can be high while suppressing an increase of the forward voltage Vf.

Therefore, these results suggest that according to embodiments, an increase of the forward voltage can be suppressed while reducing current concentration at the periphery of the n-pad electrode.

Thus, according to embodiments, a light-emitting element can be provided in which an increase of the forward voltage can be suppressed while reducing current concentration at the periphery of the n-pad electrode.

Hereinabove, exemplary embodiments of the invention are described with reference to specific examples. However, the invention is not limited to these specific examples. For example, according to the embodiments above, additions, deletions, or modifications of some of the components or processes also are included in the invention. Furthermore, the embodiments above can be implemented in combination with each other.

What is claimed is:

1. A light-emitting element comprising:
a substrate comprising:
a first side extending in a first direction in a top-view, and
a second side parallel to the first side in a top-view;
a semiconductor structure body located on the substrate, the semiconductor structure body comprising:
an n-type semiconductor layer including a first region and a second region in a top-view,
an active layer located on the second region, and
a p-type semiconductor layer located on the active layer;
an n-electrode located on the first region;
a p-electrode located on the p-type semiconductor layer;
an n-pad electrode located on the n-electrode, the n-pad electrode being more proximate to the first side than the second side in a top-view; and
a p-pad electrode located on the p-electrode, the p-pad electrode being more proximate to the second side than the first side in a top-view; wherein:
the n-electrode comprises:
a first n-electrode region extending in the first direction and overlapping the n-pad electrode in a top-view,
a second n-electrode region extending from the first n-electrode region in a second direction and overlapping the n-pad electrode in a top-view, the second direction being orthogonal to the first direction, and
a third n-electrode region extending from the second n-electrode region in the second direction and not overlapping the n-pad electrode in a top-view;
the p-electrode comprises:
a first p-electrode region extending in the first direction and overlapping the p-pad electrode in a top-view,
a second p-electrode region extending from the first p-electrode region in the second direction and overlapping the p-pad electrode in a top-view, and
a third p-electrode region extending from the second p-electrode region in the second direction and not overlapping the p-pad electrode in a top-view;
the second p-electrode region is arranged with the third n-electrode region in the first direction,
the third p-electrode region is arranged with the second n-electrode region in the first direction;
the first region comprises:
a first part positioned between the first n-electrode region and the third p-electrode region in a top-view,
a second part positioned between the second n-electrode region and the third p-electrode region in a top-view,
a third part positioned between the first p-electrode region and the third n-electrode region in a top-view, and
a fourth part positioned between the second p-electrode region and the third n-electrode region in a top-view;
a first trench that is recessed downward is located in the first and second parts but is not located in the third part.

2. The element according to claim 1, wherein:
the first trench is located in the fourth part.

3. The element according to claim 1, wherein:
the first trench is not located in the fourth part.

4. The element according to claim 1, wherein:
the first region further comprises a fifth part positioned between the third n-electrode region and the third p-electrode region in a top-view; and
the first trench is located in the fifth part.

5. The element according to claim 1, wherein:
the first region further comprises a fifth part positioned between the third n-electrode region and the third p-electrode region in a top-view; and
the first trench is not located in the fifth part.

6. The element according to claim 1, wherein:
the first region further comprises an outer perimeter part positioned between the first n-electrode region and the first side in a top-view; and
the first trench is located in the outer perimeter part.

7. The element according to claim 1, wherein:
the first region further comprises an outer perimeter part positioned between the first n-electrode region and the first side in a top-view; and
the first trench is not located in the outer perimeter part.

8. The element according to claim 1, wherein:
a width in the first direction of the first trench is not less than 3% and not more than 25% of a width in the first direction of the second part.

9. The element according to claim 1, wherein:
a depth of the first trench is less than a thickness of the second part.

10. The element according to claim 1, wherein:
a depth of the first trench is equal to a thickness of the second part.

11. The element according to claim 1, wherein:
a width in the first direction of the third n-electrode region is less than a width in the first direction of the third p-electrode region.

12. The element according to claim 1, wherein:
a distance between the first trench and the p-electrode is less than a distance between the first trench and the n-electrode.

13. A light-emitting element comprising:
a substrate comprising:
a first side extending in a first direction in a top-view, and
a second side parallel to the first side in a top-view;
a semiconductor structure body located on the substrate, the semiconductor structure body comprising:
an n-type semiconductor layer comprising a first region and a second region in a top-view,
an active layer located on the second region, and
a p-type semiconductor layer located on the active layer;
an n-electrode located on the first region;
a p-electrode located on the p-type semiconductor layer;
an n-pad electrode located on the n-electrode, the n-pad electrode being more proximate to the first side than the second side in a top-view; and
a p-pad electrode located on the p-electrode, the p-pad electrode being more proximate to the second side than the first side in a top-view; wherein:
the n-electrode comprises:
a first n-electrode region extending in the first direction and overlapping the n-pad electrode in a top-view,
a second n-electrode region extending from the first n-electrode region in a second direction and overlapping the n-pad electrode in a top-view, the second direction being orthogonal to the first direction, and
a third n-electrode region extending from the second n-electrode region in the second direction and not overlapping the n-pad electrode in a top-view;
the p-electrode comprises:
a first p-electrode region extending in the first direction and overlapping the p-pad electrode in a top-view,
a second p-electrode region extending from the first p-electrode region in the second direction and overlapping the p-pad electrode in a top-view, and
a third p-electrode region extending from the second p-electrode region in the second direction and not overlapping the p-pad electrode in a top-view;
the second p-electrode region is arranged with the third n-electrode region in the first direction,
the third p-electrode region is arranged with the second n-electrode region in the first direction,
the first region comprises:
a first part positioned between the first n-electrode region and the third p-electrode region in a top-view,
a second part positioned between the second n-electrode region and the third p-electrode region in a top-view,
a third part positioned between the first p-electrode region and the third n-electrode region in a top-view, and
a fourth part positioned between the second p-electrode region and the third n-electrode region in a top-view;
a first trench that is recessed downward is located in the first and second parts;
a second trench that is recessed downward is located in at least one of the third part or the fourth part; and
a depth of the second trench is less than a depth of the first trench.

14. The element according to claim 13, wherein:
the second trench is located in the fourth part; and
neither the first trench nor the second trench is located in the third part.

15. The element according to claim 13, wherein:
the second trench is located in the third part; and
the first trench is located in the fourth part.

16. The element according to claim 13, wherein:
the second trench is located in the third and fourth parts.

17. The element according to claim 13, wherein:
the first region further comprises a fifth part positioned between the third n-electrode region and the third p-electrode region in a top-view; and
the first trench is located in the fifth part.

18. The element according to claim 13, wherein:
the first region further comprises a fifth part positioned between the third n-electrode region and the third p-electrode region in a top-view; and
the first trench is not located in the fifth part.

19. The element according to claim 13, wherein:
the first region further comprises a fifth part positioned between the third n-electrode region and the third p-electrode region in a top-view; and
the second trench is located in the fifth part.

20. The element according to claim 13, wherein:
the first region further comprises an outer perimeter part positioned between the first n-electrode region and the first side in a top-view; and
the first trench is located in the outer perimeter part.

21. The element according to claim 13, wherein:
the first region further comprises an outer perimeter part positioned between the first n-electrode region and the first side in a top-view; and
the first trench is not located in the outer perimeter part.

22. The element according to claim 13, wherein:
a width in the first direction of the first trench is not less than 3% and not more than 25% of a width in the first direction of the second part.

23. The element according to claim 13, wherein:
a depth of the first trench is less than a thickness of the second part.

24. The element according to claim 13, wherein:
a depth of the first trench is equal to a thickness of the second part.

25. The element according to claim 13, wherein:
a width in the first direction of the third n-electrode region is less than a width in the first direction of the third p-electrode region.

26. The element according to claim 13, wherein:
a distance between the first trench and the p-electrode is less than a distance between the first trench and the n-electrode.

27. A light-emitting element comprising:
a substrate comprising:
a first side extending in a first direction in a top-view, and
a second side parallel to the first side in a top-view;
a semiconductor structure body located on the substrate, the semiconductor structure body comprising:
an n-type semiconductor layer comprising a first region and a second region in a top-view,
an active layer located on the second region, and
a p-type semiconductor layer located on the active layer;
an n-electrode located on the first region;
a p-electrode located on the p-type semiconductor layer;
an n-pad electrode located on the n-electrode, the n-pad electrode being more proximate to the first side than the second side in a top-view; and
a p-pad electrode located on the p-electrode, the p-pad electrode being more proximate to the second side than the first side in a top-view; wherein:
the n-electrode comprises:
a first n-electrode region extending in the first direction and overlapping the n-pad electrode in a top-view,
a second n-electrode region extending from the first n-electrode region in a second direction and overlapping the n-pad electrode in a top-view, the second direction being orthogonal to the first direction, and
a third n-electrode region extending from the second n-electrode region in the second direction and not overlapping the n-pad electrode in a top-view;
the p-electrode comprises:
a first p-electrode region extending in the first direction and overlapping the p-pad electrode in a top-view,
a second p-electrode region extending from the first p-electrode region in the second direction and overlapping the p-pad electrode in a top-view, and
a third p-electrode region extending from the second p-electrode region in the second direction and not overlapping the p-pad electrode in a top-view;
the second p-electrode region is arranged with the third n-electrode region in the first direction;
the third p-electrode region is arranged with the second n-electrode region in the first direction;
the first region comprises:
a first part positioned between the first n-electrode region and the third p-electrode region in a top-view,
a second part positioned between the second n-electrode region and the third p-electrode region in a top-view,
a third part positioned between the first p-electrode region and the third n-electrode region in a top-view, and
a fourth part positioned between the second p-electrode region and the third n-electrode region in a top-view;
a first trench that is recessed downward is located in the first and second parts;
a second trench that is recessed downward is located in at least one of the third part or the fourth part; and
a width in the first direction of the second trench is less than a width in the first direction of the first trench.

28. The element according to claim 27, wherein:
the second trench is located in the fourth part; and
neither the first trench nor the second trench is located in the third part.

29. The element according to claim 27, wherein:
the second trench is located in the third part; and
the first trench is located in the fourth part.

30. The element according to claim 27, wherein:
the second trench is located in the third and fourth parts.

31. The element according to claim 27, wherein:
the first region further comprises a fifth part positioned between the third n-electrode region and the third p-electrode region in a top-view; and
the first trench is located in the fifth part.

32. The element according to claim 27, wherein:
the first region further comprises a fifth part positioned between the third n-electrode region and the third p-electrode region in a top-view; and
the first trench is not located in the fifth part.

33. The element according to claim 27, wherein:
the first region further comprises a fifth part positioned between the third n-electrode region and the third p-electrode region in a top-view; and
the second trench is located in the fifth part.

34. The element according to claim 27, wherein:
the first region further comprises an outer perimeter part positioned between the first n-electrode region and the first side in a top-view; and
the first trench is located in the outer perimeter part.

35. The element according to claim 27, wherein:
the first region further comprises an outer perimeter part positioned between the first n-electrode region and the first side in a top-view; and
the first trench is not located in the outer perimeter part.

36. The element according to claim 27, wherein:
a width in the first direction of the first trench is not less than 3% and not more than 25% of a width in the first direction of the second part.

37. The element according to claim 27, wherein:
a depth of the first trench is less than a thickness of the second part.

38. The element according to claim 27, wherein:
a depth of the first trench is equal to a thickness of the second part.

39. The element according to claim 27, wherein:
a width in the first direction of the third n-electrode region is less than a width in the first direction of the third p-electrode region.

40. The element according to claim 27, wherein:
a distance between the first trench and the p-electrode is less than a distance between the first trench and the n-electrode.
